(19) United States
(12) Patent Application Publication
(10) Pub. No.: US 2026/0291453 A1
(43) Pub. Date: Sep. 24, 2026

(54) SYSTEMS AND METHODS FOR IMPEDANCE SHIFTING BETWEEN FILTERS AND AMPLIFIERS

(71) Applicant: Qorvo US, Inc., Greensboro, NC (US)

(72) Inventors: George Maxim, Saratoga, CA (US); Tabito Tanaka, Osaka (JP); Xiong Liu, Cupertino, CA (US); Baker Scott, San Jose, CA (US)

(21) Appl. No.: 19/476,379

(22) PCT Filed: May 6, 2024
(86) PCT No.: PCT/US2024/027963

§ 371 Date: Oct. 17, 2025

Related U.S. Application Data
(60) Provisional application No. 63/469,070, filed on May 26, 2023.

(51) Int. Cl. H03F 3/24; H03F 1/56; H04B 1/00; H04B 1/04; H04B 1/10; H04B 1/40

(52) U.S. Cl. CPC H03F 3/245; H03F 1/56; H04B 1/0057; H04B 1/10; H04B 1/40; H03F 2200/165; H03F 2200/222; H03F 2200/294; H03F 2200/451; H04B 2001/045; H04B 1/0475

(57) ABSTRACT

Systems and methods for impedance shifting between filters and amplifiers are disclosed. In one aspect, an active inductor that might otherwise be placed between a filter and a low noise amplifier (LNA) may be replaced with a passive impedance-boosting circuit. The impedance-boosting circuit may, for example, be a passive voltage gain circuit and may, by way of further example, be implemented with a coupled resonator filter (CRF) structure. Using such a passive voltage gain structure in receive circuits where the input noise is dominated by a noise voltage component means that any passive voltage gain in front of the active amplifier will result in a reduction of the overall receive path noise figure and may, potentially, save space that would otherwise be devoted to large inductor circuits.

### RELATED APPLICATION

This application claims the benefit of U.S. provisional patent application Ser. No. 63/469,070, filed on May 26, 2023, the disclosure of which is hereby incorporated herein by reference in its entirety.

### BACKGROUND

### I. Field of the Disclosure

The technology of the disclosure relates generally to impedance-matching for amplifiers in a transceiver circuit.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to facilitate high-bandwidth wireless communication. This pressure has led to evolving cellular and wireless standards with operation in various frequency bands. This variated operation generally requires separate receive chains in the wireless circuitry, and each receive chain may have its own low noise amplifier (LNA). Ensuring each LNA operates efficiently may require impedance-matching between the LNA and a respective filter. Optimizing this impedance matching provides room for innovation.

### SUMMARY

Aspects disclosed in the detailed description include systems and methods for impedance shifting between filters and amplifiers. In particular, exemplary aspects of the present disclosure contemplate replacing an active inductor that might otherwise be placed between a filter and a low noise amplifier (LNA) with a passive impedance-boosting circuit. The impedance boosting circuit may, for example, be a passive voltage gain circuit and may, by way of further example, be implemented with a coupled resonator filter (CRF) structure. Using such a passive voltage gain structure in receive circuits where the input noise is dominated by a noise voltage component means that any passive voltage gain in front of the active amplifier will result in a reduction of the overall receive path noise figure and may, potentially, save space that would otherwise be devoted to large inductor circuits.

In this regard, in one aspect, a receiver chain is disclosed. The receiver chain includes an LNA comprising an input and a band-select filter coupled to the input, the band-select filter comprising a filter, and an impedance boosting circuit configured to provide a passive impedance boost.

In another aspect, a CRF structure is disclosed. The CRF structure includes a first input side comprising a first number of interdigital fingers, a first output side comprising a second number of interdigital fingers where the second number of interdigital fingers is less than the first number of interdigital fingers, and a reflector coupled to a first one of the first number of interdigital fingers, wherein a difference between the first number and the second number of interdigital fingers creates a passive impedance boost between the first input side and the first output side.

In another aspect, a computing device is disclosed. The computing device includes a transceiver including a baseband processor and a receiver chain coupled to the baseband processor, the receiver chain including an LNA comprising an input and a band-select filter coupled to the input, the band-select filter comprising a filter and an impedance boosting circuit configured to provide a passive impedance boost.

In another aspect, a method for controlling a receiver chain is disclosed. The method includes receiving a signal at an antenna and filtering the signal. The method also includes boosting impedance in a path of the signal using a CRF impedance boosting circuit and providing the signal to an input of an LNA.

### BRIEF DESCRIPTION OF THE DRAWINGS

FIG. 1 is a block diagram of a conventional receive chain having multiple receive paths, each with an impedance-matching inductor in each receive path;

FIG. 2A is a block diagram of a single receive chain with an impedance boosting circuit according to exemplary aspects of the present disclosure;

FIG. 2B is a block diagram of a receiver with multiple receive chains, each receive chain having an impedance boosting circuit according to exemplary aspects of the present disclosure;

FIG. 3A is block diagram of a first possible implementation of the impedance boosting circuit of the present disclosure after a filter;

FIG. 3B is a block diagram of a second possible implementation of the impedance boosting circuit of the present disclosure integrated into a filter;

FIG. 3C is a block diagram of a third possible implementation of the impedance boosting circuit as an intermediate circuit between filters;

FIG. 4A is a block diagram of an impedance boosting circuit used in a shared transmit and receive filter, such as might occur in a time division duplex (TDD) system;

FIG. 4B is a block diagram of an impedance boosting circuit used in a separate receive filter, such as might occur in a frequency division duplex (FDD) system;

FIG. 5A is a block diagram of an impedance-boosting circuit used with a tuned low noise amplifier (LNA);

FIG. 5B is a block diagram of an impedance-boosting circuit used with an active match LNA;

FIGS. 6A-6D are diagrams of possible impedance-boosting circuits based on different coupled-resonator-filter (CRF) structures;

FIG. 7 is a diagram of two parallel CRF structures that may be used for impedance-boosting circuits;

FIG. 8 is a diagram of two parallel CRF structures that used a shared reflector to reduce implementation area;

FIG. 9A is a first aspect of a hybrid resonator-CRF structure that may be used as a combined filter and impedance-boosting circuit;

FIG. 9B is a second aspect of a resonator that may be used in a hybrid resonator-CRF structure;

FIG. 9C is a third aspect of a resonator that may be used in a hybrid resonator-CRF structure;

FIG. 10 shows the hybrid structure of FIG. 9A implemented in an FDD-based transceiver chain;

FIG. 11 is a block diagram of an implementation of the matched LNA of FIG. 5B;

FIG. 12 is a block diagram of an alternate implementation of the LNA of FIG. 11 but with a common source amplifier;

FIG. 13 is a block diagram of an alternate impedance boosting circuit that allows the elimination of the impedance rotation inductance;

FIG. 14 is a block diagram of an aspect of the present disclosure combined with a distortion cancelation circuit; and

FIG. 15 is a block diagram of a mobile terminal that may include the impedance-boosting circuits of the present disclosure described herein.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include systems and methods for impedance shifting between filters and amplifiers. In particular, exemplary aspects of the present disclosure contemplate replacing an active inductor that might otherwise be placed between a filter and a low noise amplifier (LNA) with a passive impedance boosting circuit. The impedance boosting circuit may, for example, be a passive voltage gain circuit and may, by way of further example, be implemented with a coupled resonator filter (CRF) structure. Using such a passive voltage gain structure in receive circuits where the input noise is dominated by a noise voltage component means that any passive voltage gain in front of the active amplifier will result in a reduction of the overall receive path noise figure and may, potentially, save space that would otherwise be devoted to large inductor circuits.

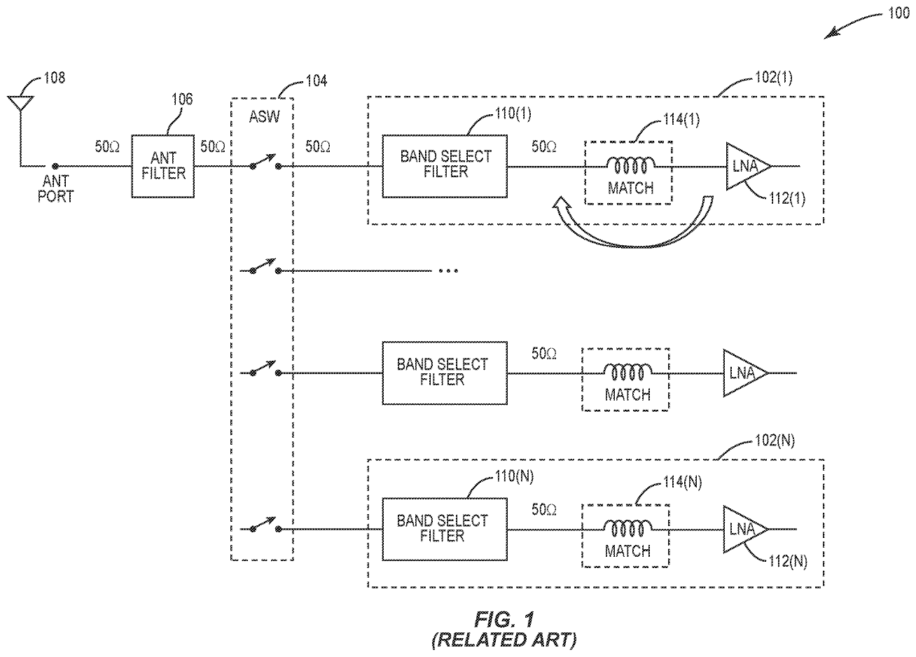

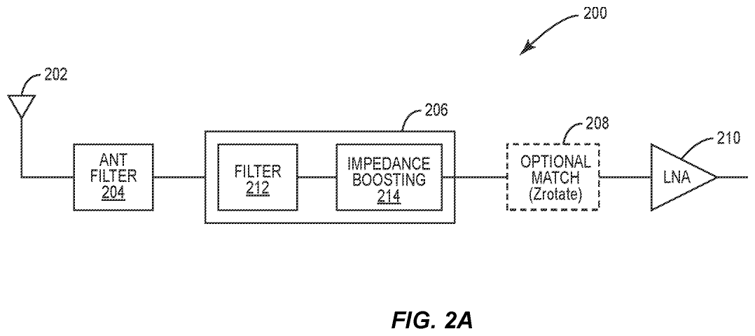

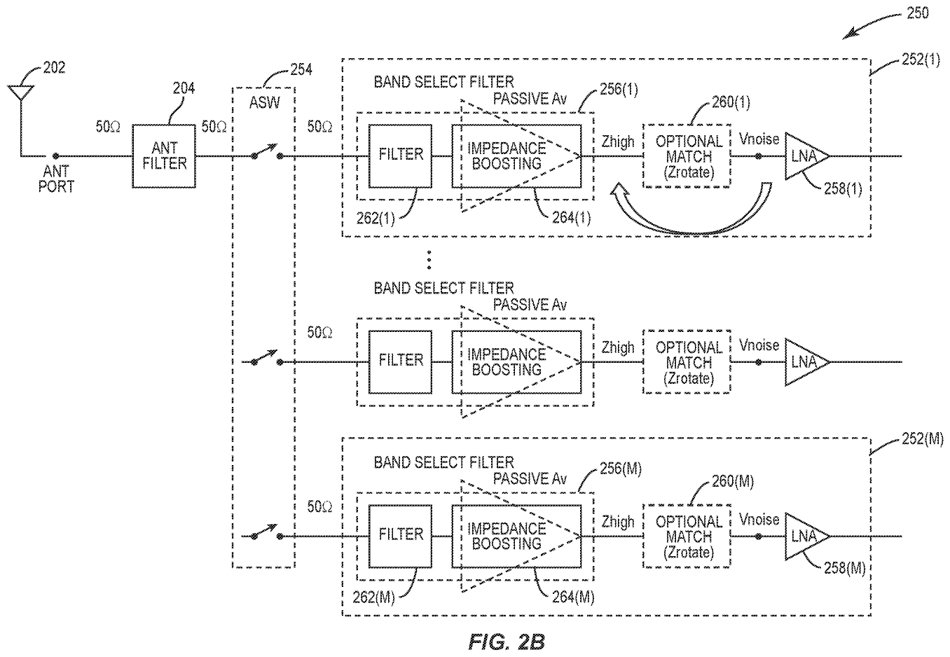

Before addressing specific aspects of the present disclosure, a brief overview of existing receive chains is provided with reference to FIG. 1. This discussion will provide context to highlight the advantages of the present disclosure, a discussion of which begins below with reference to FIG. 2A.

In this regard, FIG. 1 is a block diagram of a conventional receive chain 100 having multiple receive paths 102(1)-102(N). Each receive path 102(1)-102(N) is coupled to an antenna switch 104. The antenna switch 104 (also referred to as ASW in the Figures) selectively couples one of the receive paths 102(1)-102(N) to an antenna filter 106 and an antenna 108. In practice, a consistent impedance is provided to reduce reflections and make interoperation more readily effectuated. A common impedance is fifty ohms (50Ω). Thus, the antenna filter 106 has an input impedance of 50 ohms (i.e., at the antenna port), and the antenna switch 104 has an input impedance of 50 ohms. Further, each receive path 102(1)-102(N) has a band select filter 110(1)-110(N) that has an input impedance of 50 ohms. Each receive path 102(1)-102(N) may further have an LNA 112(1)-112(N). The LNA 112(1)-112(N) typically has a higher impedance, and an impedance-matching inductor 114(1)-114(N) is used to effectuate impedance-matching. The LNAs 112(1)-112(N) may be bipolar junction transistor (BJT) type amplifiers, but more commonly, the LNAs 112(1)-112(N) are field effect transistor (FET) type amplifiers.

Inductors such as impedance-matching inductors 114(1)-114(N) are generally comparatively large relative to other circuitry within a transceiver. In some cases, the inductors are off-chip, requiring multiple in/out pins, which also consumes space. Thus, having multiple impedance-matching inductors 114(1)-114(N) requires a large amount of real estate for the impedance-matching function. In an existing device, for example, such impedance-matching inductors 114(1)-114(N) may use more space than the circuitry that implements the LNAs 112(1)-112(N). Still further, the impedance-matching inductors 114(1)-114(N) may also add series resistance to the receive paths 102(1)-102(N). Such series resistance may negatively impact a noise factor or otherwise degrade performance.

Exemplary aspects of the present disclosure contemplate adding an impedance-boosting circuit within the filter circuitry. In an exemplary aspect, the impedance boosting circuit may be a coupled resonator-filter (CRF) structure. Since many filters rely on resonator structures, this approach allows the filter to be implemented on the same die as the CRF structure. The CRF structure may be implemented so that an output of the CRF structure has a higher impedance level than the filter and act as a passive voltage gain circuit. In addition to the space-saving benefits, there may be noise benefits. Specifically, many active devices used in building LNAs are transconductance stages such as, for example, metal oxide semiconductor (MOS) transistors, junction field effect transistors (JFETs), pseudomorphic high electron mobility transistors (pHEMTs), and the like. In use, such active devices typically have a large input impedance and a small or negligible input radio frequency (RF) current. As such, these active devices will perform mainly input voltage processing. Because of this voltage processing, a passive voltage gain in front of the active LNA will result in a reduction in noise contribution coming from the active devices. This reduction results in an overall reduction of the noise of the entire receive path. Such noise reduction improves performance.

By way of further explanation, a passive impedance transformation stage comes intrinsically with a passive voltage gain equal to the square root of the impedance ratio (minus the insertion of loss of the passive stage). If the active device is an input voltage processing one (e.g., a transconductance device), the input noise is dominated by the noise voltage, and a passive voltage gain in front of the active stage noise will result in a reduction of the active noise contribution back at the source node.

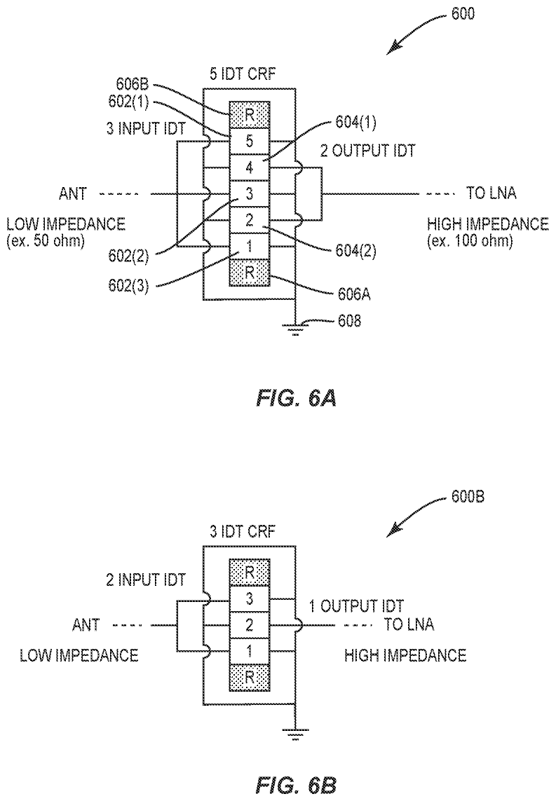

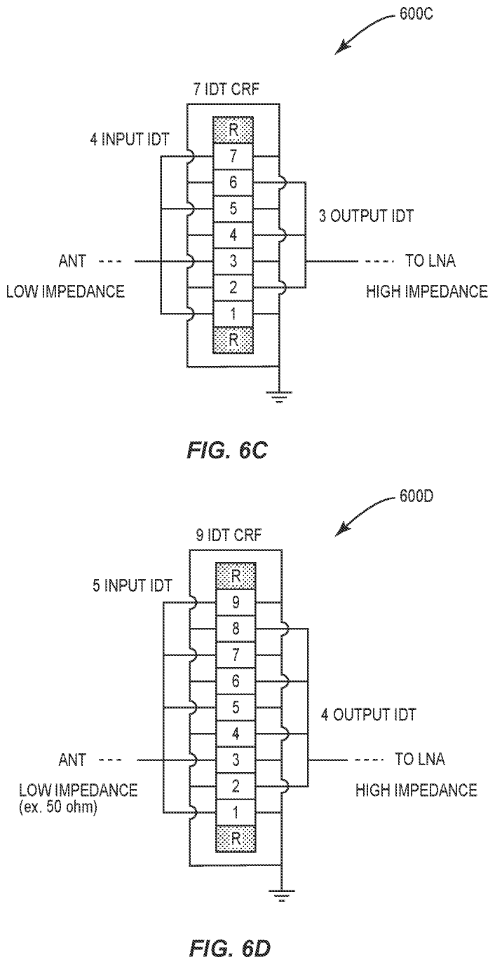

In this regard, FIG. 2A is a block diagram of a single receive chain 200 with an impedance-boosting circuit according to exemplary aspects of the present disclosure. More specifically, the receive chain 200 includes an antenna 202 coupled to an antenna filter 204. Signals received through the antenna 202 are filtered and then passed to a band-select filter 206. There may be an optional match circuit 208 that couples the band-select filter 206 to an LNA 210. The band-select filter 206 may include a filter 212, which may, for example, be an acoustic filter such as a surface acoustic wave (SAW) filter, a bulk acoustic wave (BAW) filter, or the like. The band-select filter 206 may further include an impedance-boosting circuit 214, which may, as mentioned above, be a CRF structure. Other structures are also possible without departing from the present disclosure. More details on possible CRF implementations are provided below, beginning with reference to FIG. 6A.

While FIG. 2A shows a single receive chain 200, as noted above, in many cases, a receiver 250 may include a plurality of receive circuits 252(1)-252(M), as better illustrated in FIG. 2B. The antenna 202 and the antenna filter 204 may be shared by the plurality of receive circuits 252(1)-252(M). An antenna switch 254 may selectively couple a given receive circuit 252(1)-252(M) to the shared antenna 202, as is well understood. As with the receive chain 200, each of the receive circuits 252(1)-252(M) has a respective band select filter 256(1)-256(M) and LNA 258(1)-258(M). Optionally, a respective match circuit 260(1)-260(M) may also be present. The band select filters 256(1)-256(M) have respective filters 262(1)-262(M) and impedance boosting circuits 264(1)-264(M).

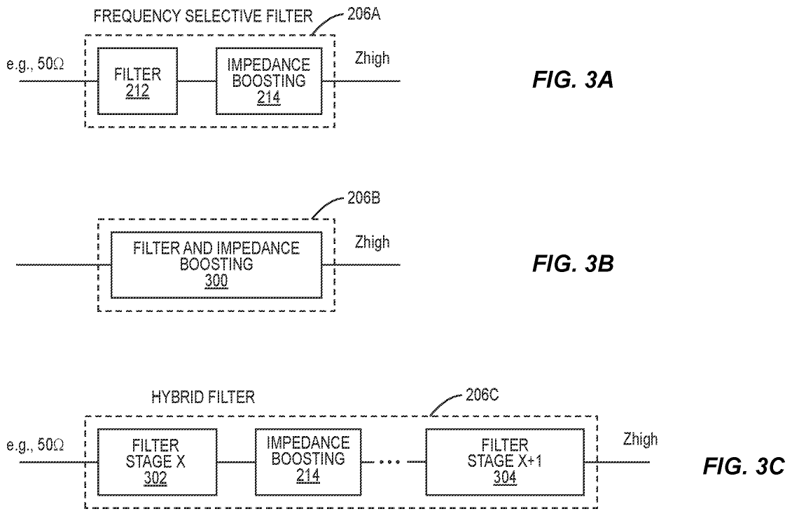

FIG. 3A is block diagram of a first possible implementation of the band-select filter 206A, and specifically contemplates that the impedance-boosting circuit 214 is positioned after the filter 212. In contrast, in-band-select filter 206B, illustrated in FIG. 3B, the impedance boosting circuit is combined with the filter as a hybrid circuit 300. As still another option is provided by band-select filter 206C, illustrated in FIG. 3C. Specifically, the impedance boosting circuit 214 is positioned between a first filter stage 302 and a subsequent filter stage 304, with the understanding that there may be many filter stages (not illustrated) and the impedance boosting circuit could be between any two stages (e.g., between first and second, between third and fourth, between eighth and ninth, xth and (x+1)th, or the like). As alluded to elsewhere, the filters 212 and filter stages 302, 304 may be resonators, and the impedance boosting circuit 214 may include a CRF structure. The use of resonators in both structures allows the band-select filters to be constructed on a single die using similar resonator manufacturing technologies.

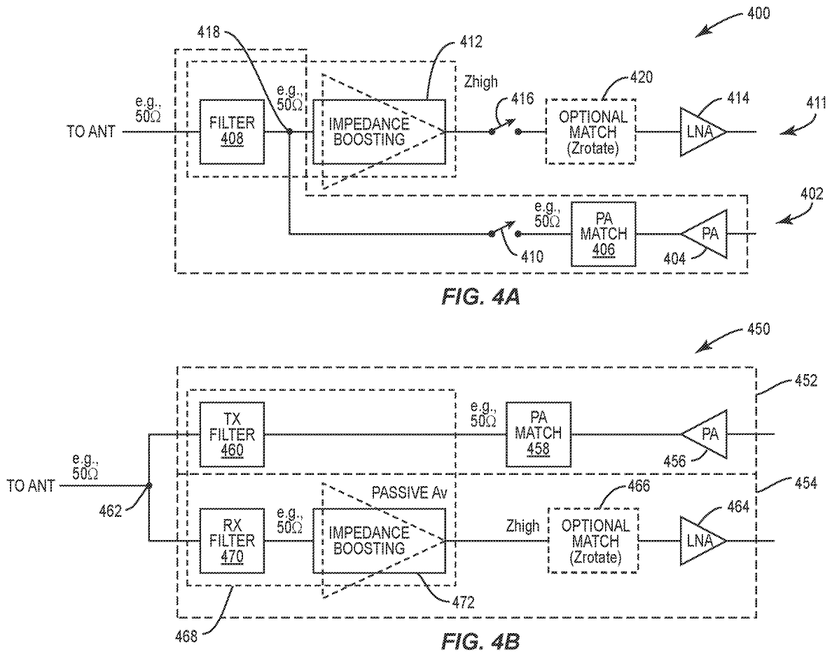

There may be transceiver architectures that use the impedance-boosting circuit that may share the filter with a transmit chain, as illustrated in FIG. 4A. More specifically, a transceiver 400 may include a transmit chain 402 having a power amplifier 404 and a power amplifier-matching circuit 406 that couples to a filter 408 by a switch 410. The filter 408 may couple to an antenna filter 204 and an antenna 202 (neither shown in FIG. 4A). The filter 408 may also be part of a receive chain 411. More specifically, the filter 408 may couple to an impedance-boosting circuit 412, which in turn also couples to an LNA 414 through a switch 416. Chains 402 and 411 are combined at node 418 if desired. As with earlier structures, an optional matching circuit 420 may be present. Such a shared approach is appropriate but not required for a time division duplex (TDD) transceiver.

Alternatively, and in transceivers that have simultaneous send and receive operations, such as a frequency division duplex (FDD) transceiver 450 illustrated in FIG. 4B, there may be separate transmit and receive chains 452, 454. The transmit chain 452 may include a power amplifier 456, a power amplifier match circuit 458, and a transmit filter 460. The transmit filter 460 may couple to the antenna filter 204 and the antenna 202 (neither shown in FIG. 4B) through a node 462. The receive chain 454 may include an LNA 464, an optional matching circuit 466, and a band select filter 468. The band select filter 468 may include a receive filter 470 and an impedance boosting circuit 472.

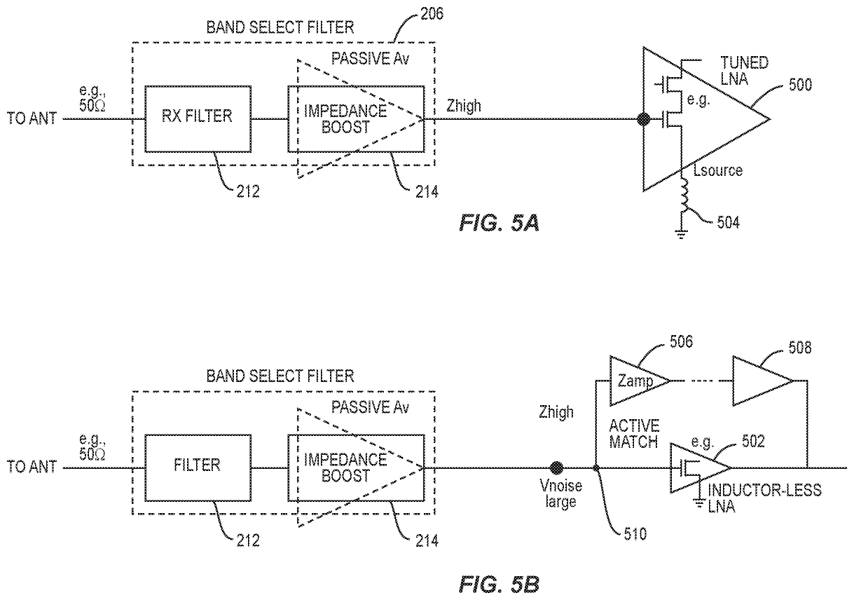

The impedance boosting circuit of the present disclosure may be used with different types of LNAs. For example, the impedance-boosting circuits of the present disclosure may be used with tuned LNAs and active match LNAs, as illustrated in FIGS. 5A and 5B, respectively. Thus, FIG. 5A illustrates a band-select filter 206 having the impedance boosting circuit 214 coupled to a tuned LNA 500. The tuned LNA 500 may have a lower noise factor than an active match LNA 502 of FIG. 5B. The turned LNA may use a passive input matching technique such as source degeneration (i.e., inductor 504) and an optional gate tuning inductance (not shown). The gate tuning inductance adds back in the inductors for which the impedance boosting circuit is designed to eliminate and, as such, may be a suboptimal approach if space-saving concerns are paramount. However, the use of the impedance-boosting circuit 214 allows the quality factor of any gate-tuning inductance to be relaxed, and a smaller inductor may be used. Further, if the tuned LNA 500 uses an input voltage processing device (with dominant input noise voltage), then a passive voltage gain block implemented with a passive impedance transformation stage (i.e., impedance-boosting circuit 214) will result in overall noise improvement.

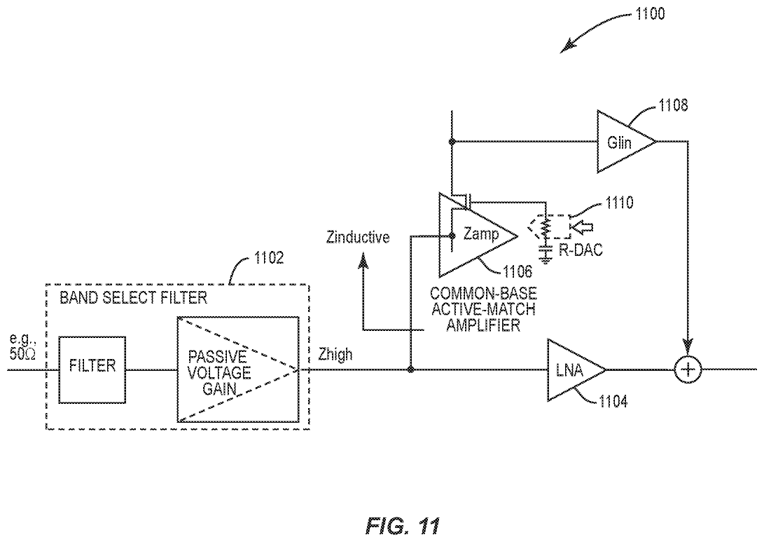

The active LNA 502 of FIG. 5B may include an active impedance amplifier 506. In some aspects, there may be a second amplifier 508. The amplifiers 506, 508 are positioned in parallel to the LNA 502. The use of the active impedance amplifier 506 (and optionally the second amplifier 508) allows for the elimination of both the inductor 504 and the gate inductor, but the combination of amplifiers 502, 506, and 508 has a higher noise factor. An advantage of the active input match is that an active input match allows for a broader S11 matching that may be useful for a broader range of communication bands. The drawback is the noise injected at the input by the active impedance amplifier 506 may need to be canceled at an output to get reasonable noise performance for the receive path. Having a high impedance at an LNA input 510 gives an advantage since both the noise contribution of the active LNA 502 and the active impedance amplifier 506 are reduced by the passive voltage gain created by the impedance boosting circuit 214. Additional details about the use of active match amplifiers are provided below with reference to FIGS. 11-13.

Against the backdrop of the various possible ways in which an impedance boosting circuit may be used, FIGS. 6A-6D provide diagrams of possible impedance boosting circuits based on different coupled-resonator-filter (CRF) structures. In particular, FIG. 6A illustrates a five-digit interdigital transducer (IDT) 600 with three digits 602(1)-602(3) being on an input side and two digits 604(1)-604(2) being on an output side. The difference in digits between the input side and the output side contributes to the impedance boost of the circuit. A larger number of digits creates a larger capacitance and, thus, a lower impedance. Reflectors 606A and 606B may be used to assist in controlling signal propagation by using an acoustic structure to eliminate high losses. Further, the digits may be coupled to a ground 608, as shown.

FIGS. 6B-6D show three-digit, seven-digit, and nine-digit IDT structures 600B-600D, respectively. As explained above, the imbalance of digits between the input and output sides contributes to the impedance boost. Empirical evidence and modeling show that the three-digit IDT structure 600B may provide an optimal impedance boost given size and performance criteria.

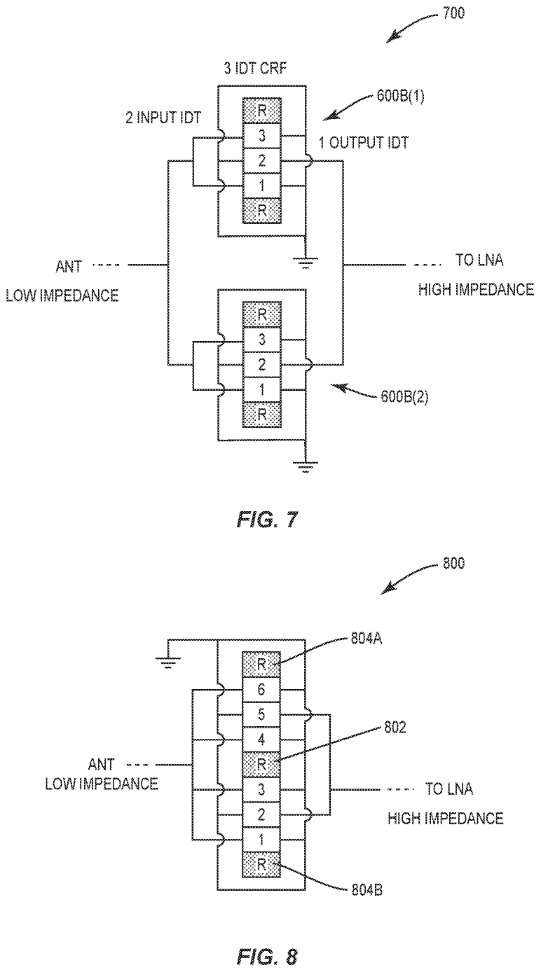

While a three-digit IDT structure 600B may be optimal, the present disclosure contemplates combined structures such as two parallel three-digit IDT structures 600B(1)-600B(2) of an impedance boosting circuit 700 illustrated in FIG. 7 to reduce insertion loss caused by the impedance boosting circuit.

Space may be further conserved when using parallel structures by sharing a reflector 802 between parallel three-digit IDT structures 600B(1)-600B(2), as better illustrated by impedance boosting circuit 800 in FIG. 8. End reflectors 804A, 804B may still be present.

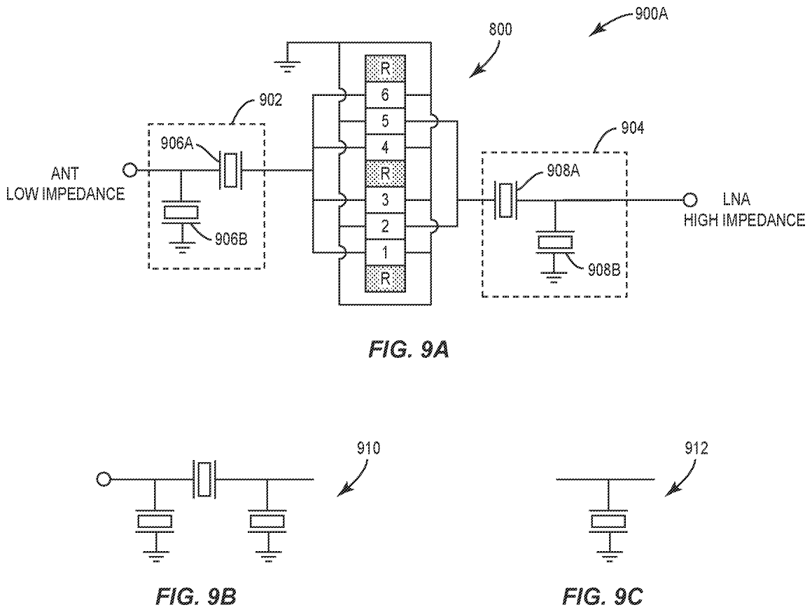

FIGS. 9A-9C provide further illustration of possible resonator-based ladder filter structures that may be used with the impedance boosting circuit 800 (or other IDT structures if needed or desired). These ladder filter structures are provided by way of example and are not intended to be limiting. In particular, FIG. 9A illustrates a band-select filter 900A that has CRF structure 800, an input filter 902, and an output filter 904. The input filter 902 may be formed by two resonators 906A, 906B that mimic an L-shaped LC-filter. Likewise, the output filter 904 may be formed by two resonators 908A, 908B, which also mimic an L-shaped LC-filter. Alternatively, as illustrated in FIG. 9B, either the input filter 902 or output filter 904 may be replaced with a pi-filter 910. As still another alternative, the input filter 902 or output filter 904 may be replaced by a single resonator 912 coupled to the ground.

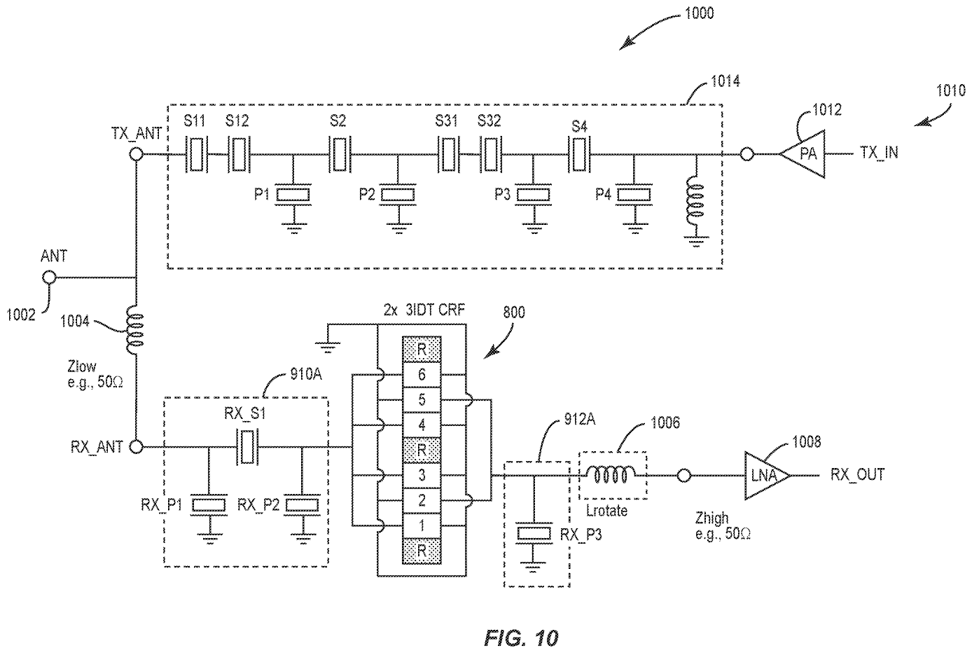

FIG. 10 illustrates additional details as the filters of FIGS. 9A-9C and the impedance boosting circuit 800 are implemented into an FDD-based transceiver chain 1000. Specifically, signals received at an antenna 1002 are first filtered by an inductor 1004 (analogous to the antenna filter 204) and then provided to a pi-shaped filter 910A. The signal is then boosted by the impedance boosting circuit 800 before an additional filter 912A is used. As discussed above, there may be an optional rotate circuit 1006 before an LNA 1008. On a transmit chain 1010, signals are amplified by a power amplifier 1012 before being filtered by a filter 1014 and then passed to the antenna 1002.

FIGS. 11-13 show more details about possible active matched LNAs. In particular, FIG. 11 contemplates a receive chain 1100 with a band select filter 1102 and an LNA 1104. The LNA 1104 has a first common base active match amplifier 1106 and a second amplifier 1108 in parallel. The first common base active match amplifier 1106 uses a resistive digital-to-analog converter (DAC) 1110 to make the first common base active match amplifier 1106 look like an inductor and thus may allow the match circuit (which may be an inductor) to be omitted.

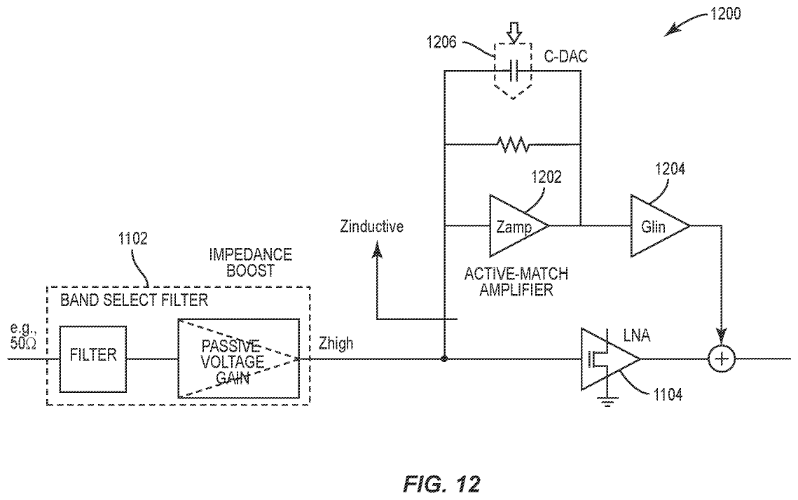

Similarly, the receive chain 1200 of FIG. 12 also includes a first amplifier 1202, and a second amplifier 1204 in parallel with the LNA 1104. However, here the first amplifier 1202 is not a common base amplifier and uses a capacitor DAC 1206 to make the first amplifier 1202 look like an inductor.

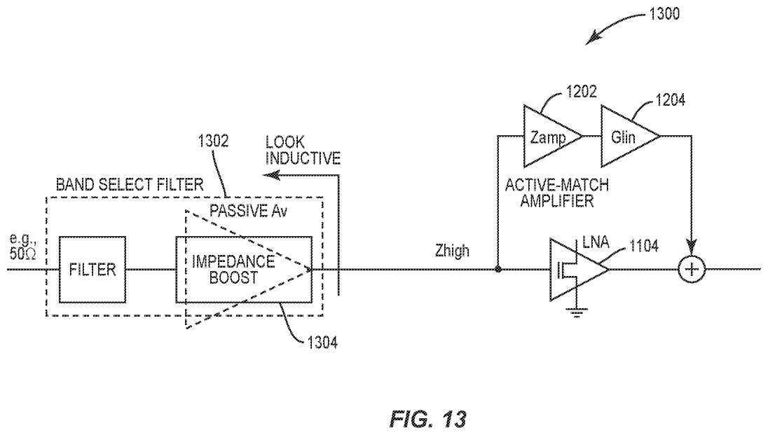

In contrast, the receive chain 1300 of FIG. 13 adds the inductance to the band select filter 1302 and specifically to the impedance boosting circuit 1304. This may require a higher linearity LNA 1104 but, otherwise, is substantially similar.

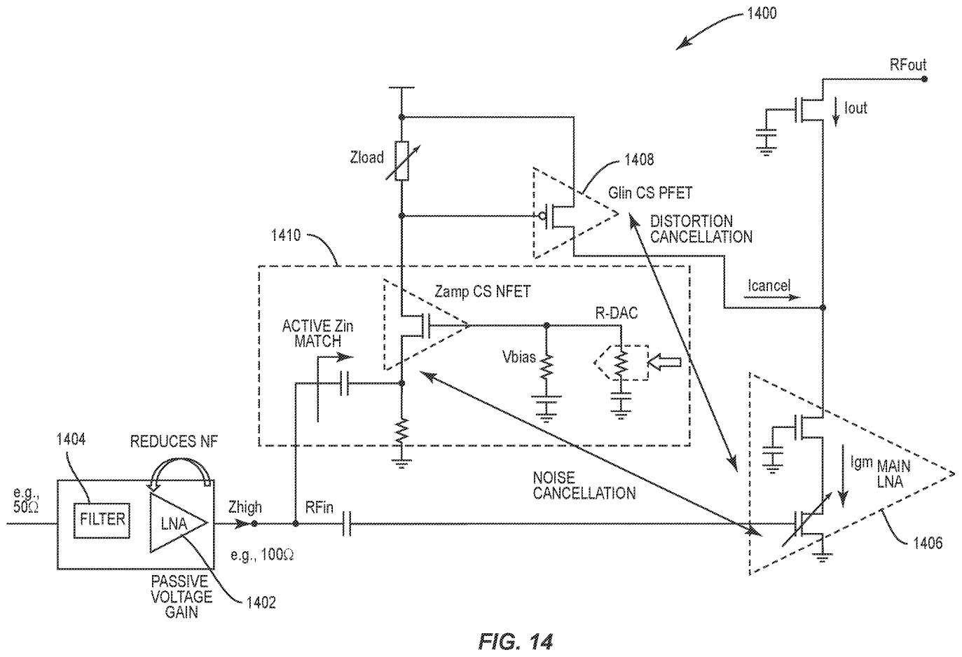

Exemplary aspects of the present disclosure may also be combined with distortion cancelation circuitry, as illustrated in FIG. 14. Specifically, a receive chain 1400 may have an LNA 1402 with a band select filter 1404 as a first stage and a second LNA 1406. Distortion circuitry 1408 may be used with the second LNA 1406 along with noise cancelation circuitry 1410.

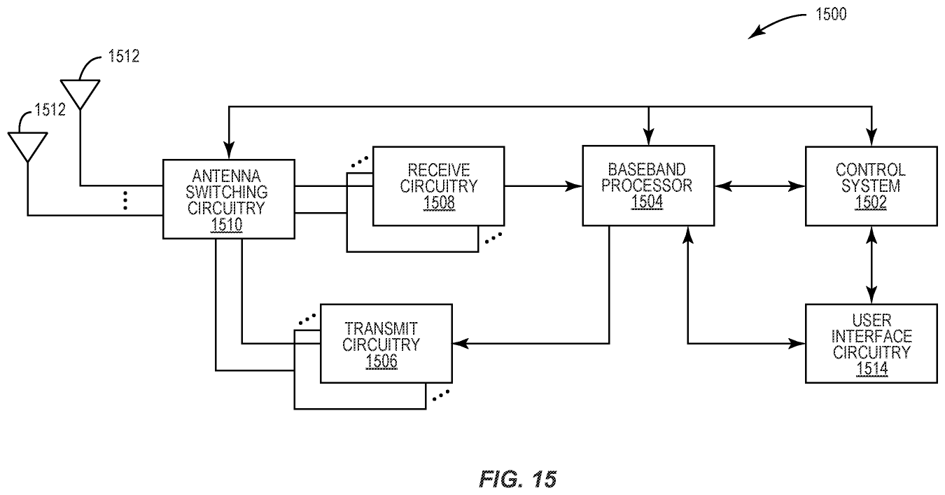

FIG. 15 is a block diagram of a mobile terminal that may include the impedance-boosting circuits of the present disclosure described herein. With reference to FIG. 15, the power management circuits described above may be implemented in various types of user elements 1500, such as mobile terminals, smart watches, tablets, computers, navigation devices, access points, and like wireless communication devices that support wireless communications, such as cellular, wireless local area network (WLAN), Bluetooth, and near field communications. The user elements 1500 will generally include a control system 1502, a baseband processor 1504, transmit circuitry 1506, receive circuitry 1508, antenna switching circuitry 1510, multiple antennas 1512, and user interface circuitry 1514. In a non-limiting example, the control system 1502 can be a field-programmable gate array (FPGA) or an application-specific integrated circuit (ASIC), as an example. In this regard, the control system 1502 can include at least a microprocessor(s), an embedded memory circuit(s), and a communication bus interface(s). The receive circuitry 1508 receives radio frequency signals via the antennas 1512 and through the antenna switching circuitry 1510 from one or more base stations. A low noise amplifier and a filter of the receive circuitry 1508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1504 processes the digitized received signal to extract the information or data bits conveyed in the received signal. This processing typically comprises demodulation, decoding, and error correction operations. The baseband processor 1504 is generally implemented in one or more digital signal processors (DSPs) and ASICs.

For transmission, the baseband processor 1504 receives digitized data, which may represent voice, data, or control information, from the control system 1502 that it encodes for transmission. The encoded data is output to the transmit circuitry 1506, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1512 through the antenna switching circuitry 1510. According to the present disclosure, power management circuits may work with the power amplifier to assist in providing efficient operation of the power amplifier. The multiple antennas 1512 and the replicated transmit and receive circuitries 1506, 1508 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A receiver chain comprising:
a low noise amplifier (LNA) comprising an input; and
a band-select filter coupled to the input, the band-select filter comprising a filter, and an impedance-boosting circuit distinct from the filter and configured to provide a passive impedance boost.

2. The receiver chain of claim 1, wherein the LNA comprises a tuned LNA, wherein the tuned LNA comprises a source degeneration inductor (504) to provide passive input matching.

3. The receiver chain of claim 1, wherein the LNA comprises an active matched LNA, wherein the active matched LNA comprises two parallel amplifiers.

4. The receiver chain of claim 1, wherein the filter comprises a resonator.

5. The receiver chain of claim 4, wherein the impedance-boosting circuit comprises a coupled resonator filter (CRF) structure.

6. The receiver chain of claim 1, wherein the filter comprises an input filter relative to the impedance-boosting circuit.

7. The receiver chain of claim 1, wherein the filter comprises an output filter relative to the impedance-boosting circuit.

8. The receiver chain of claim 5, wherein the CRF structure comprises an input side comprising a first plurality of interdigital fingers and an output side comprising a second plurality of interdigital fingers.

9. The receiver chain of claim 8, wherein the first plurality of interdigital fingers comprises more fingers than the second plurality of interdigital fingers.

10. The receiver chain of claim 9, wherein the first plurality of interdigital fingers comprises three interdigital fingers.

11. The receiver chain of claim 4, wherein the CRF comprises:
a first input side comprising a first number of interdigital fingers;
a first output side comprising a second number of interdigital fingers where the second number of interdigital fingers is less than the first number of interdigital fingers; and
a reflector coupled to a first one of the first number of interdigital fingers, wherein a difference between the first number of interdigital fingers and the second number of interdigital fingers creates a passive impedance boost between the first input side and the first output side.

12. The receiver chain of claim 11, wherein the first number of interdigital fingers is three.

13. The receiver chain of claim 12, wherein the second number of interdigital fingers is two.

14-18. (canceled)

19. The receiver chain of claim 1 integrated into a computing device, the computing device comprising:
a transceiver comprising:
a baseband processor.

20. A method for controlling a receiver chain, comprising:
receiving a signal at an antenna;
filtering the signal with a filter;
boosting impedance in a path of the signal using a coupled resonator filter (CRF) impedance boosting circuit wherein the CRF is distinct from and different from the filter; and
providing the signal to an input of a low noise amplifier (LNA).
